(19) United States
(12) Patent Application Publication
(10) Pub. No.: US 2014/0130861 A1
(43) Pub. Date: May 15, 2014

(54) SOLAR CELL

(71) Applicant: Sanyo Electric Co., Ltd., Moriguchi City (JP)

(72) Inventor: Yuya Nakamura, Hyogo (JP)

(73) Assignee: Sanyo Electric Co., Ltd., Moriguchi City (JP)

(21) Appl. No.: 14/159,677

(22) Filed: Jan. 21, 2014

Related U.S. Application Data
(63) Continuation of application No. PCT/JP2012/056859, filed on Mar. 16, 2012.

(30) Foreign Application Priority Data
Jul. 27, 2011 (JP) 2011-163823

(51) Int. Cl. H01L 31/0232; H01L 31/0224

(52) U.S. Cl. CPC H01L 31/02327; H01L 31/022425
USPC 136/256

(57) ABSTRACT

The solar cell (1) of the present invention is provided with: a photoelectric conversion unit (10); a transparent conductive layer (15) provided on the surface of the photoelectric conversion unit (10); a metal layer (17) provided on the transparent conductive layer (15); and an intermediate layer (20) which has a smaller extinction coefficient than that of the metal layer (17) and which is provided between the transparent conductive layer (15) and the metal layer (17). Evanescent light generated at the interface between the photoelectric conversion unit (10) and the transparent conductive layer (15) is less readily absorbed by the intermediate layer (20), and the proportion of the metal layer (17) which readily absorbs evanescent light can be reduced in the area in which evanescent light is standing. As a result, it is possible to suppress a decrease in optical reflectance by the metal layer (17), and to increase the utilization efficiency of light.

### CROSS-REFERENCE TO RELATED APPLICATIONS

This is a continuation of International Application PCT/JP2012/056859, with an international filing date of Mar. 16, 2012, filed by applicant, the disclosure of which is hereby incorporated by reference in its entirety.

### FIELD OF THE INVENTION

The present invention relates to a solar cell.

### BACKGROUND

Solar cells have attracted attention in recent years as an energy source with a low environmental impact. A solar cell is described in Patent Document 1 which has a semiconductor substrate, a silicon layer arranged on the main surface of the semiconductor substrate on the back surface side, a transparent conductive layer arranged on the silicon layer, and a reflective layer of Ag arranged on the transparent conductive layer.

### PRIOR ART DOCUMENTS

### Patent Documents

Patent Document 1: PCT Application Translation No. 8-508368

### SUMMARY

### Problem Solved by the Invention

There has been growing demand in recent years for a solar cell with even greater photoelectric conversion efficiency.

The present invention provides a solar cell with improved photoelectric conversion efficiency.

### Means of Solving the Problem

The solar cell of the present invention includes a photoelectric conversion unit, a metal layer, and an intermediate layer. The photoelectric conversion unit includes a transparent conductive layer on a surface. The metal layer is arranged on the transparent conductive layer. The intermediate layer is arranged between the metal layer and the transparent conductive layer. The intermediate layer has a smaller extinction coefficient than that of the metal layer.

### Effect of the Invention

The present invention is able to provide a solar cell with improved photoelectric conversion efficiency.

### BRIEF DESCRIPTION OF THE DRAWINGS

FIG. 1 is a simplified cross-sectional view of the solar cell in an embodiment.

FIG. 2 is a simplified rear view of the solar cell in the embodiment.

FIG. 3 is a simplified cross-sectional view in which a portion of the solar cell in the embodiment has been enlarged. In FIG. 3, the cross-sectional hatching has been omitted.

FIG. 4 is a graph representing the optical reflectance of the metal layer of the solar cell in the embodiment at an optical wavelength of 1000 nm.

FIG. 5 is a graph representing the reflectivity of the metal layer of the solar cell in the embodiment at an optical wavelength of 1000 nm.

FIG. 6 is a graph representing the reflectivity of the metal layer of the solar cell in a reference example at an optical wavelength of 1000 nm.

### DETAILED DESCRIPTION

The following is an explanation of examples of preferred embodiments of the present invention. The following embodiments are merely examples. The present invention is not limited by the following embodiments in any way.

Further, in each of the drawings referenced in the embodiments, members having substantially the same function are denoted by the same symbols. The drawings referenced in the embodiments are also depicted schematically. The dimensional ratios of the objects depicted in the drawings may differ from those of the actual objects. The dimensional ratios of objects may also vary between drawings. The specific dimensional ratios of the objects should be determined with reference to the following explanation.

### 1st Embodiment

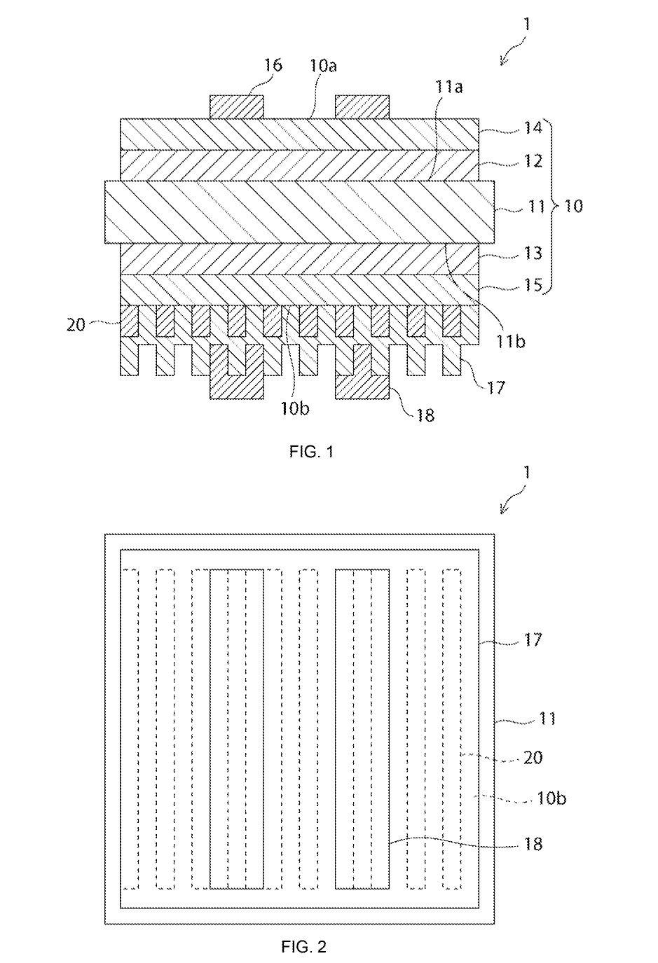

FIG. 1 is a simplified cross-sectional view of the solar cell 1 in an embodiment. FIG. 2 is a simplified rear view of the solar cell 1.

The solar cell 1 has a photoelectric conversion unit 10. The photoelectric conversion unit 10 is the portion which generates carriers such as electrons and holes when exposed to light. The photoelectric conversion unit 10 has a substrate 11, first and second semiconductor layers 12, 13, and first and second transparent conductive layers 14, 15.

The substrate 11 is a substrate made of a semiconductor material. The substrate 11 has one type of conductivity. The substrate 11 can be constructed of a substrate made of crystalline silicon, such as a substrate of single-crystal silicon. The thickness of the substrate 11 can be 300 μm or less. The substrate 11 has first and second main surfaces 11a, 11b.

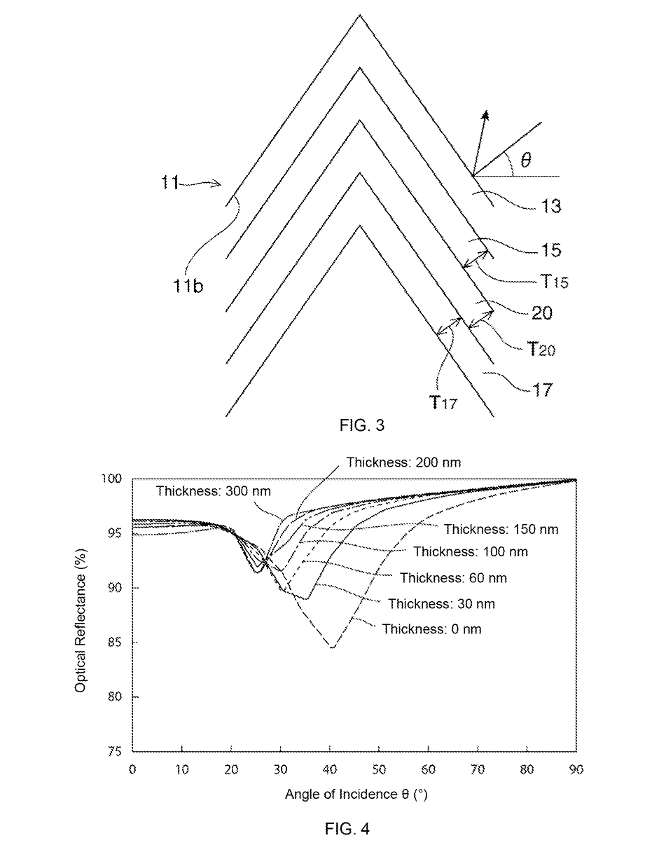

In the present embodiment, as shown in FIG. 3, each of the first and second main surfaces 11a, 11b has a textured structure. Here, “textured structure” means an uneven structure formed to suppress surface reflection and increase the amount of light absorbed by the photoelectric conversion unit. A specific example of a textured structure is a pyramidal uneven structure (pyramid or truncated pyramid) obtained by performing anisotropic etching on the surface of a single-crystal silicon substrate having a (100) plane.

A first semiconductor layer 12 is arranged on the first main surface 11a. Meanwhile, a second semiconductor layer 13 is formed on the second main surface 11b. One of the first and second semiconductor layers 12, 13 has the same type of conductivity as the substrate 11, and the other has a type of conductivity different from that of the substrate 11. The semiconductor layers 12, 13 can be made of p-type or n-type amorphous silicon. The structure of the solar cell in the present embodiment is called a HIT (registered trademark) structure.

A substantially intrinsic i-type semiconductor layer having a thickness from several ∪ to 250 ∪ that does not substantially influence the generation of power may be arranged between the semiconductor layers 12, 13.

A first transparent conductive layer 14 is arranged on the first semiconductor layer 12. The first transparent conductive layer 14 is provided so as to substantially cover the entire first semiconductor layer 12. The light-receiving surface 10a of the photoelectric conversion unit 10 is composed of the surface of the first transparent conductive layer 14.

A linear electrode (busbar portion and finger portions) 16 made of a metal such as Ag or an alloy is arranged on the first transparent conductive layer 14. This electrode 16 collects either electron or hole carriers.

A second transparent conductive layer 15 is arranged on the second semiconductor layer 13. The second transparent conductive layer 15 is provided so as to substantially cover the entire second semiconductor layer 13. The back surface 10b of the photoelectric conversion unit 10 is composed of the surface of the second transparent conductive layer 15. The light-receiving surface 10a is the main surface that primarily receives light. The solar cell 1 may generate electricity when receiving light only on the light-receiving surface 10a, or may be a bifacial light-receiving solar cell which generates electricity when receiving light on both the light-receiving surface 10a and the back surface 10b.

The transparent conductive layers 14, 15 can be composed of indium tin oxide (ITO), indium zinc oxide (IZO), aluminum zinc oxide (AZO), or gallium zinc oxide (GZO).

The thickness of the transparent conductive layers 14, 15 is 100 nm or less. In the present specification, layer thickness refers to the thickness in the direction normal to the surface of the layer, and not the thickness in the thickness direction of the substrate 11. Specifically, the thickness of the transparent conductive layer 15 is thickness T₁₅ in FIG. 3.

A metal layer 17 is arranged on the second transparent conductive layer 15. The metal layer 17 substantially covers the entire second transparent conductive layer 15. A linear electrode 18 made of a metal such as Ag or an alloy is arranged on the metal layer 17. The electrode 18 may have a finger portion and a busbar portion. In the solar cell 1, one of the carriers, electrons or holes, is collected by electrode 18 and the metal layer 17, and the other is collected by electrode 16.

The metal layer 17 also functions as a reflective layer. At least some of the light incident from the light-receiving surface 10a that reaches the metal layer 17 is reflected again towards the light-receiving surface 10a.

The metal layer 17 is preferably of at least one type of metal selected from a group including Ag, Cu, Ni, Mn, Cr, Sn, Mg, W, Co and Zn. Among these a metal layer 17 of Ag is preferred.

The thickness T₁₇ of the metal layer 17 is preferably from 100 nm to 400 nm, and more preferably from 150 nm to 300 nm. This increases the optical reflectance of the metal layer 17 while also reducing the electrical resistivity of the metal layer 17.

An intermediate layer 20 is provided between the transparent conductive layer 15 and at least a portion of the metal layer 17. The intermediate layer 20 may be provided over the entire area in which the metal layer 17 is provided but, in the present invention, the intermediate layer 20 is arranged between the transparent conductive layer 15 and a portion of the metal layer 17. In other words, the intermediate layer 20 is arranged in a portion of the area in which the metal layer 17 is provided. More specifically, as shown in FIG. 2, the intermediate layer 20 is provided as stripes extending parallel to each other at intervals in the area in which the metal layer 17 is provided.

From the standpoint of reducing the electrical resistivity, the area percentage for the area in which the intermediate layer 20 is provided relative to the area in which the metal layer 17 is provided is preferably from 20% to 80%, and more preferably from 30% to 70%.

The intermediate layer 20 has a higher electrical resistivity than the metal layer 17. Here, the electrical resistivity is determined as a general rule using carrier concentration and carrier mobility. When the carrier concentration is higher, the electrical resistivity tends to be lower. When the carrier concentration is lower, the electrical resistivity tends to be higher. However, the extinction coefficient is correlated with the carrier concentration, as understood from the Drude equation explained below. When the carrier concentration is higher, the extinction coefficient is higher. When the carrier concentration is lower, the extinction coefficient is lower. In other words, there is a correlation between electrical resistivity and the extinction coefficient. More specifically, when the carrier concentration is high and the electrical resistivity is low, the extinction coefficient is higher. When the carrier concentration is low and the electrical resistivity is high, the extinction coefficient is lower. Therefore, an intermediate layer 20 with an electrical resistivity that is higher than the metal layer 17 also has an extinction coefficient that is lower than the metal layer 17.

Equation 1

N=n·1 k=\sqrt{t₂₈ (1−A/E²−i EΓ)} (Drude Equation)

In the Drude equation, N is the complex refractive index, n is the refractive index, i is an imaginary number, k is the extinction coefficient, E is the energy of the incident light, A is a coefficient proportional to the carrier concentration, and ε_{∞} and F are both coefficients unrelated to the carrier concentration.

The electrical resistivity of the intermediate layer 20 is greater than the electrical resistivity of the metal layer 17 preferably by a factor of 100 or more, and more preferably by a factor of 50 or more. More specifically, the electrical resistivity of the intermediate layer 20 is preferably 1×10⁻³ Ω·cm or more, and more preferably 5×10⁻³ Ω·cm or more.

The extinction coefficient of the intermediate layer 20 is smaller than the extinction coefficient of the metal layer 17 preferably by a factor of 0.01 or less, and more preferably by a factor of 0.002 or less. More specifically, the extinction coefficient of the intermediate layer 20 is preferably 0.1 or less, and more preferably 0.02 or less.

The intermediate layer 20 can be made of at least one type of material selected from a group including magnesium fluoride, silicon nitride, aluminum oxide, calcium fluoride, and magnesium oxide.

The refractive index of the intermediate layer 20 is preferably higher than the refractive index of the metal layer 17 but lower than the refractive index of the transparent conductive layer 15. The refractive index of the intermediate layer 20 is higher than the refractive index of the metal layer 17 preferably by 0.1 or more, and more preferably by 0.2 or more. The refractive index of the intermediate layer 20 is lower than the refractive index of the transparent conductive layer 15 preferably by 0.1 or more, and more preferably by 0.2 or more. More specifically, the refractive index of the intermediate layer 20 is preferably from 0.3 to 2.5, and more preferably from 1 to 2.

The thickness T₂₀ of the intermediate layer 20 is preferably 100 nm or more. The thickness of the intermediate layer 20 is preferably less than the thickness of the metal layer 17. In other words, the thickness of the metal layer 17 is preferably greater than the thickness of the intermediate layer 20.

However, a metal layer 17 functioning as a reflective layer has an electrical resistivity that is lower than the transparent conductive layer 15. Therefore, the extinction coefficient of the metal layer 17 is high. As a result, evanescent light occurring at the interface between the second semiconductor layer 13 and the transparent conductive layer 15 is readily absorbed by the metal layer 17. When evanescent light is absorbed by the metal layer 17, optical reflectance of the metal layer 17 is reduced by the amount of absorbed evanescent light. Here, evanescent light refers to the light leaking slightly towards the transparent conductive layer 15 or the metal layer 17 when all of the light is reflected at the interface between the second semiconductor layer 13 and the transparent conductive layer 15. This evanescent light is absorbed by the transparent conductive layer 15 and the metal layer 17. Therefore, the absorption of evanescent light by the transparent conductive layer 15 and the metal layer 17 has to be taken into account when reflectance is considered. This reduces the utilization efficiency of the light. As a result, the photoelectric conversion efficiency declines.

For this reason, an intermediate layer 20 is provided between the transparent conductive layer 15 and at least a portion of the metal layer 17 in the solar cell 1. The intermediate layer 20 has an electrical resistivity that is higher than the metal layer 17. Thus, the extinction coefficient of the intermediate layer 20 is smaller than the extinction coefficient of the metal layer 17. As a result, the evanescent light occurring at the interface of the second semiconductor layer 13 and the transparent conductive layer 15 is less readily absorbed by the intermediate layer 20. By arranging this intermediate layer 20 between the metal layer 17 and the transparent conductive layer 15, the percentage of the area in which the metal layer 17 readily absorbs evanescent light can be reduced relative to the area in which evanescent light is standing. Therefore, the absorption of light occurring in the interface between the second semiconductor layer 13 and the transparent conductive layer 15 can be suppressed. As a result, reduction of the optical reflectance by the metal layer 17 can be suppressed, the utilization efficiency of light can be increased, and improved photoelectric conversion efficiency can be realized.

In an embodiment able to increase the optical reflectance of the metal layer 17 and improve the utilization efficiency of light, the thickness of the semiconductor substrate 11 is preferably reduced, and the amount of light passing though the substrate 11 increased. More specifically, the thickness of the substrate 11 is more preferably 300 μm or less.

Another way to prevent the metal layer 17 from being located in the area in which evanescent light generated at the interface between the second semiconductor layer 13 and the transparent conductive layer 15 is standing would be to increase the thickness of the transparent conductive layer 15. However, this increases the amount of light absorbed by the transparent conductive layer 15. This is counterproductive as it reduces the utilization efficiency of the light.

In contrast, the thickness of the transparent conductive layer 15 does not have to be increased in the solar cell 1. As a result, any increase in the amount of light absorbed by the transparent conductive layer 15 can be suppressed.

From the standpoint of more effectively suppressing the absorption of light by the metal layer 17, it is preferable for the percentage of the area in which the intermediate layer 20 is provided to be increased relative to the area in which the metal layer 17 is provided, and for the intermediate layer 20 to be substantially provided in the entire region in which the metal layer 17 is provided. However, when the percentage of the area in which the intermediate layer 20 is provided is increased relative to the area in which the metal layer 17 is provided, the electrical resistivity of the intermediate layer 20 is higher than the electrical resistivity of the metal layer 17, and the resistance between the transparent conductive layer 15 and the metal layer 17 tends to increase. Therefore, the photoelectric conversion efficiency of the solar cell 1 may be reduced. From this standpoint, the percentage of the area in which the intermediate layer 20 is provided relative to the area in which the metal layer 17 is provided is preferably from 20% to 80%, and more preferably from 30% to 70%.

FIG. 4 is a graph representing the reflectivity of the metal layer at an optical wavelength of 1000 nm. In the graph shown in FIG. 4, the data is obtained from a simulation performed under the following conditions. The thickness shown in FIG. 4 is the thickness of the intermediate layer 20. The horizontal axis in FIG. 4 is the angle of incidence (θ).

The intermediate layer 20 is provided in the entire region in which the metal layer 17 is provided.

2nd semiconductor layer 13: 9.1 nm-thick amorphous silicon layer.

Transparent conductive layer 15: 61.5 nm-thick indium oxide layer doped with W dopant.

Intermediate layer 20: Magnesium fluoride layer.

Metal layer 17: 400 nm-thick Ag layer.

It is clear from the graph shown in FIG. 4 that the optical reflectance of the metal layer 17 can be increased by providing an intermediate layer 20 with an electrical resistivity greater than that of the metal layer 17 but with an extinction coefficient that is smaller. It is also clear that the optical reflectance of the metal layer 17 can be increased even further when the thickness of the intermediate layer 20 is 100 nm or greater. From these results, it is clear that the thickness of the intermediate layer 20 is preferably 100 nm or greater. However, when the intermediate layer 20 is too thick and the intermediate layer 20 is thicker than the metal layer 17, the portion in which the metal layer 17 is positioned above the intermediate layer 20 and the portion in which the metal layer 17 is positioned in the region where the intermediate layer 20 is not provided may become decoupled in the metal layer 17 forming process due to a coverage problem. Therefore, the thickness of the intermediate layer 20 is preferably smaller than the thickness of the metal layer 17. In other words, the thickness of the metal layer 17 is preferably greater than the thickness of the intermediate layer 20.

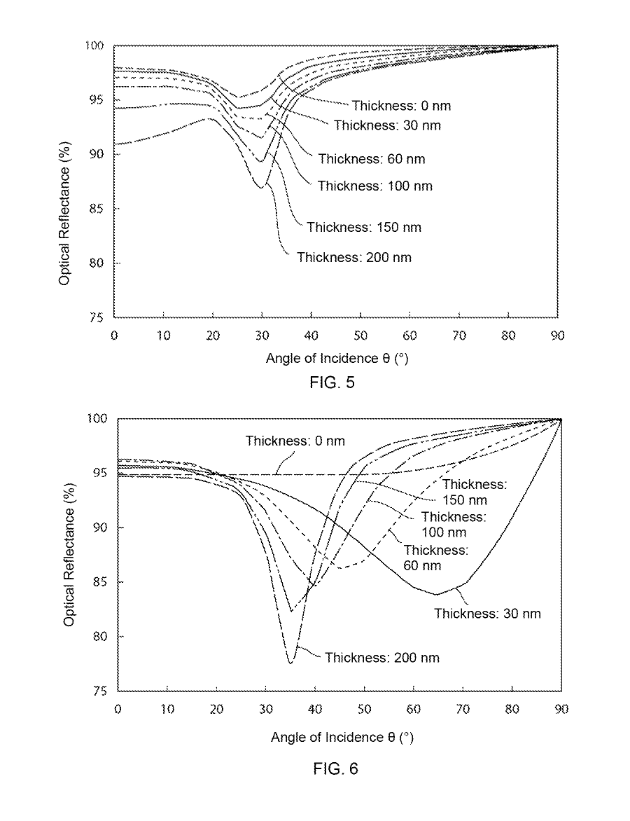

FIG. 5 is a graph representing the reflectivity of the metal layer of the solar cell in the present embodiment at an optical wavelength of 1000 nm. In the data shown in FIG. 5, the data is obtained from a simulation performed under the following conditions. The thickness shown in FIG. 5 is the thickness of the transparent conductive layer 15.

The intermediate layer 20 is provided in the entire region in which the metal layer 17.

2nd semiconductor layer 13: 9.1 nm-thick amorphous silicon layer.

Transparent conductive layer 15: indium oxide layer doped with W dopant.

Intermediate layer 20: 61.5 nm-thick magnesium fluoride layer.

Metal layer 17: 400 nm-thick Ag layer.

FIG. 6 is a graph representing the reflectivity at an optical wavelength of 1000 nm of the metal layer of a solar cell in a reference example having a configuration substantially identical to the solar cell in the embodiment, except that an intermediate layer 20 is not provided. The thickness shown in FIG. 6 is the thickness of the transparent conductive layer.

It is clear from the graphs in FIG. 5 and FIG. 6 that when an intermediate layer 20 is provided the minimum value of optical reflectance decreases monotonically as the thickness of the transparent conductive layer 15 increases. This does not occur when an intermediate layer 20 is not provided. It is clear from these results that the thickness of the transparent conductive layer 15 is preferably 100 nm or less when an intermediate layer 20 is provided.

Also, the refractive index of the intermediate layer 20 is preferably higher than the refractive index of the metal layer 17 but lower than the refractive index of the transparent conductive layer 15. Here, the light interference effect increases the reflectance.

The present invention includes many embodiments not described herein. For example, the intermediate layer 20 may be provided over the entire area in which the metal layer 17 is provided. In this case, the absorption of evanescent light can be more effectively suppressed.

The photoelectric conversion unit does not have to have a HIT structure. Polycrystalline silicon, thin-film silicon, or CIGS may be used.

The solar cell may also be a back contact solar cell in which the first and second electrodes are arranged on a single main surface.

The present invention includes many other embodiments not described herein. Therefore, the technical scope of the present invention is defined solely by the items of the invention specified in the claims pertinent to the above explanation.

### Key to the Drawings

1: Solar cell

10: Photoelectric conversion unit

11: Substrate

12: 1st semiconductor layer

13: 2nd semiconductor layer

14: 1st transparent conductive layer

15: 2nd transparent conductive layer

17: Metal layer

20: Intermediate layer

What is claimed is:

1. A solar cell comprising:
a photoelectric conversion unit including a transparent conductive layer on a surface;
a metal layer arranged on the transparent conductive layer; and
an intermediate layer arranged between the metal layer and the transparent conductive layer, the intermediate layer having a smaller extinction coefficient than the metal layer.

2. The solar cell according to claim 1, wherein the intermediate layer has a higher electrical resistivity than the metal layer, and is arranged between the transparent conductive layer and a portion of the metal layer.

3. The solar cell according to claim 2, wherein the area ratio of the area in which the intermediate layer is provided relative to the area in which the metal layer is provided is from 20% to 80%.

4. The solar cell according to claim 2, wherein the thickness of the metal layer is greater than the thickness of the intermediate layer.

5. The solar cell according to claim 1, wherein the refractive index of the intermediate layer is greater than the refractive index of the metal layer, but less than the refractive index of the transparent conductive layer.

6. The solar cell according to claim 1, wherein the intermediate layer is made of at least one type of material selected from a group including magnesium fluoride, silicon nitride, aluminum oxide, calcium fluoride, and magnesium oxide.

7. The solar cell according to claim 1, wherein the metal layer is made of at least one type of element selected from a group including Ag, Cu, Ni, Mn, Cr, Sn, Mg, W, Co, and Zn.

8. The solar cell according to claim 1, wherein the photoelectric conversion unit includes a substrate made of crystalline silicon, and the thickness of the substrate is 300 μm or less.
